(19) United States
(12) Patent Application Publication
(10) Pub. No.: US 2026/0123501 A1
(43) Pub. Date: Apr. 30, 2026

(54) Semiconductor Substrate Bonder with Enhanced Alignment via Digital Twin and Machine Learning

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/926,308

(22) Filed: Oct. 25, 2024

(51) Int. Cl. H01L 23/00

(52) U.S. Cl. CPC H10W 72/0711; H10W 72/07113; H10W 72/07173; H10W 72/07178; H10W 72/07183

(57) ABSTRACT

The present invention relates to a high-precision substrate alignment method and system for semiconductor bonding, utilizing advanced sensory systems, digital twin technology, and machine learning. Unique alignment marks, such as 2D barcodes and varied critical dimension (CD) grids, capture precise positional information of substrates in 3D space. This system optimizes movement trajectories for substrate bonding, significantly improving alignment accuracy and process efficiency.

### FIELD OF THE INVENTION

The present invention relates to methods and systems for achieving high-precision alignment in substrate bonding processes, particularly in semiconductor manufacturing and advanced packaging technologies. The invention utilizes advanced sensors, digital twins, and machine learning techniques to improve alignment accuracy, addressing limitations in conventional optical-based alignment systems for next-generation packaging requirements.

### BACKGROUND OF THE INVENTION

Substrate bonding is a critical process in the fabrication of multi-layer semiconductor devices, including 3D integrated circuits (3D ICs) and other advanced packaging solutions such as wafer-to-wafer (W2W) and die-to-wafer (D2W) bonding. Precise alignment of wafers or dies is essential to ensure device functionality and performance. Misalignment can cause defects, reduced yield, and suboptimal device performance, making accurate alignment a key requirement in advanced packaging technologies.

Conventional alignment systems typically use optical cameras to detect alignment marks and adjust substrate positions. In W2W bonding, the optical camera detects marks on both wafers and adjusts their positions to achieve proper alignment. Similarly, in D2W bonding, alignment is performed by either aligning the wafer to a mark on the holder or placing a camera between the die and a reference die on the base wafer to measure alignment. While these systems are automated, they face challenges in meeting the precision demands of the semiconductor industry's roadmap for advanced packaging.

As packaging architectures become more complex, alignment accuracy must reach sub-micron or even nanometer levels. However, current optical systems struggle to achieve such precision, particularly when faced with issues like substrate warpage, thickness variations, and process-induced distortions. These factors create errors that conventional optical systems cannot adequately correct, leading to misalignment that affects bonding quality and device performance. The trend toward more complex packaging has highlighted the limitations of traditional alignment methods. Advanced packaging demands far greater precision than these systems can provide, necessitating more innovative alignment solutions. The present invention addresses these challenges by integrating advanced sensory systems, digital twin technology, and machine learning algorithms to enable real-time, high-precision alignment in substrate bonding processes.

### SUMMARY

The present invention provides a novel method and system for achieving high-precision alignment in substrate bonding processes, utilizing advanced alignment marks and computational techniques. Wafer-to-wafer (W2W) and die-to-wafer (D2W) bonding serve as illustrative examples, though the system and method are applicable to various substrate types, including silicon interposers, organic interposers, and glass substrates, with no restriction on shape or size. A key innovation is the introduction of novel alignment marks, such as 2D barcodes or varied critical dimension (CD) grids, which significantly enhance the accuracy of substrate position determination. Unlike conventional methods that rely primarily on optical camera-based detection of two alignment marks for real-time adjustments, the proposed system shifts much of the alignment process to computational techniques, employing digital twins and machine learning.

These alignment marks, whether 2D barcodes or varied CD grids, provide unique positional data captured by a sensory system. This data allows for more precise determination of the alignment marks'positions in three-dimensional (3D) space by analyzing specific patterns or CD variations. Based on this analysis, the system calculates substrate positions with greater accuracy than conventional optical methods. The operating parameters for controlling the movements of the stage holding a base substrate and the bonding head holding a top substrate are computed using a calibrated digital twin or a trained neural network. These positions are represented in a shared 3D coordinate system, accounting for any registered offsets of the alignment marks. The computed operating parameters define the precise trajectories required to align the substrates.

Various embodiments of the invention utilize different types of sensors to capture alignment mark data. In one embodiment, high-resolution optical cameras detect the 2D barcodes, while in another, reflectometry or electron beam sensors capture localized measurements of the varied CD grids. These measurements are processed to generate the operating parameters that adjust the substrates'positions for high-precision alignment.

The system further enhances precision by leveraging digital twins and neural networks. Digital twins create virtual representations of the substrates, sensors, and stages, allowing continuous monitoring and real-time calibration throughout the bonding process. A neural network analyzes input data, such as registered offsets caused by lithography overlay errors, substrate warpage, or thickness variations, and generates optimized operating parameters to minimize misalignment during bonding.

In contrast to conventional methods that depend directly on camera-based detection, the proposed system relies on computational modeling and simulation. The digital twin enables predictive adjustments and corrections, significantly improving substrate alignment accuracy.

Overall, the integration of novel alignment marks with digital twin technology and machine learning marks a significant advancement in alignment precision, providing a robust solution to the challenges of next-generation semiconductor packaging.

### BRIEF DESCRIPTIONS OF DRAWINGS

To enhance clarity, the following description refers to the accompanying drawings:

FIG. 1A: Depicts a schematic representation of an exemplary bonder after the base substrate is loaded onto a movable stage.

FIG. 1B: Depicts a schematic representation of the exemplary bonder after the top substrate is positioned above the base substrate by a moving mechanism, with the top substrate facing upward toward the sensory system.

FIG. 1C: Depicts a schematic representation of the exemplary bonder after the top substrate is flipped to face downward toward the base substrate.

FIG. 1D: Depicts a schematic functional diagram of the exemplary bonder, illustrating its key components and their interactions.

FIG. 2A: Showcases a first embodiment of the sensory system using an image capture device and a vertical position sensor, where a 2D barcode is used for determining the position of the substrate in 3D space.

FIG. 2B: Showcases a second embodiment of the sensory system using a reflectometry sensor and the vertical position sensor, where a varied critical dimension (CD) grid with an example is used for determining the position of the substrates in 3D space.

FIG. 2C: Showcases a third embodiment of the sensory system using an electron beam (e-beam) CD metrology sensor and the vertical position sensor, where a varied CD grid is used for determining the position of the substrates in 3D space.

FIG. 3: Details a flowchart of the operations of the bonder for aligning the base substrate and the top substrate.

FIG. 4: Illustrates an alignment neural network for determining the operating parameters of the movable stage and the moving mechanism.

FIG. 5: Depicts a schematic representation of the digital twin for an exemplary bonder, including virtual representations of key subsystems.

FIG. 6: Shows a flowchart outlining the process of training the neural network and applying the trained neural network for alignment optimization.

FIG. 7: Showcases a schematic representation of a D2W bonder utilizing the novel alignment method, including the use of a 2D barcode or varied CD grid for positioning.

### DETAILED DESCRIPTIONS

This section provides detailed embodiments of the present invention to ensure a comprehensive understanding. Specific examples are provided for clarity, but modifications and variations that align with the claims are considered within the scope of this invention. Conventional methods and components are discussed where relevant to underscore the distinct features of the invention.

### Definitions of Terms

Alignment Mark: A predefined pattern or structure placed on a substrate, such as a wafer or die, used as a reference for determining the position or orientation of the wafer or die in a bonding process. The alignment mark may take various forms, including 2D barcodes, varied critical dimension (CD) grids, or other patterns designed for precise positional identification during alignment.

2D Barcode: A matrix-style code storing data in both X and Y directions, typically comprising small squares or dots. In the context of substrate alignment, a spot on the 2D barcode provides 2D positional information to guide the movement of substrates during the alignment process.

Varied Critical Dimension (CD) Grid: A 2D pattern where a spot on the grid contains a unique collection of lines and spaces. When measured by a reflectometry sensor, the spot with a unique signature provides 2D positional information to guide the movement of substrates during the alignment process.

Wafer-to-Wafer Bonding (W2W Bonding): A process in which two wafers are aligned and bonded together to form a multi-layer structure. This technique is commonly used in 3D integrated circuit (3D IC) fabrication and advanced packaging, where precise alignment is critical.

Die-to-Wafer Bonding (D2W Bonding): A process in which individual dies are aligned and bonded to a wafer. Frequently used in advanced semiconductor packaging, this method requires precise alignment of each die with the target wafer.

Digital Twin: A virtual representation of a physical object or system, including its properties, behavior, and operational state. In this invention, a digital twin of the bonder models components such as the substrate, stages, and moving mechanism, providing real-time feedback and optimization during the alignment process.

Neural Network: A computational model that recognizes patterns, optimizes parameters, and makes decisions based on input data. In this invention, a neural network analyzes measured positional data of the substrates, optimizes movements of the stage and moving mechanism, and improves bonding precision.

Reflectometry Sensor: A sensor that measures the intensity or phase of reflected light to determine the properties of a surface or object. In alignment, a reflectometry sensor captures localized measurements from an alignment mark, such as a varied CD grid, to determine precise substrate positions.

e-Beam Metrology Sensor: A sensor using an electron beam to determine surface properties. In alignment, an e-beam metrology sensor scans a spot on a 2D barcode or varied CD grid to determine the precise positions of the substrates.

Movable Stage: A mechanical platform capable of moving in at least two directions (X and Y axes) for positioning a base substrate with high precision. In some implementations, the platform can also move in the Z direction. In alignment processes, a movable stage controls the base substrate's position.

Moving Mechanism: A programmable mechanism capable of multi-directional movement and performing tasks such as picking, placing, or aligning objects, such as a 6-axis robotic arm. In alignment, the moving mechanism positions the top substrate.

Stage Actuator: A component responsible for controlling the movement of the movable stage in various directions. It may include motors, piezoelectric elements, or other mechanisms to achieve fine motion control required for substrate positioning.

Operating Parameters: Variables controlling the movements, actions, or settings of a machine or system. In bonding, operating parameters may include the positions, velocities, and accelerations of the stage or moving mechanism, as well as alignment tolerances, ensuring precise substrate placement.

Hybrid Bonding: A semiconductor bonding technique involving the initial bonding of dielectric layers followed by the bonding of conductive interconnects, typically through an annealing process. This method allows for high-density, multi-layer structures.

Real-Time (RT) Data: Data collected and processed instantly or with minimal delay during operation. In substrate bonding, real-time data includes positional measurements, calibration updates, and substrate warpage, which are used to dynamically adjust operating parameters.

Substrate Warpage: Deformation or bending of a substrate caused by stresses during manufacturing processes such as deposition, etching, or thermal cycling. Warpage affects substrate flatness, complicating alignment, bonding, and lithography. Accurate measurement and compensation for warpage are critical for maintaining alignment precision in advanced packaging and 3D ICs.

Calibration Data: Information collected during the calibration process, comparing and adjusting the system's measurements against known standards to ensure precision. In bonding, calibration data for the stage and moving mechanism is essential for refining operating parameters.

Registered Offset: A pre-determined spatial difference between the alignment mark and the bonding pads or target feature, often due to lithography variations. In bonding, registered offsets ensure alignment compensates for positional shifts during bonding.

Monte Carlo Methods: A computational algorithm that uses random sampling to obtain numerical results, often employed to simulate complex systems with statistical variations. Monte Carlo methods help assess positional variations and optimize alignment processes.

Simulated Annealing (SA): An optimization method that mimics the annealing process in materials, using a probabilistic approach to explore solution spaces. SA is effective in optimizing complex, non-convex problems like multi-parameter alignment processes.

Stochastic Gradient Descent (SGD): An optimization method used to minimize functions by iteratively updating parameters with randomly selected data subsets. It is often used in training neural networks for alignment optimization due to its computational efficiency.

Newton-Raphson Method: A root-finding algorithm that uses second-order derivatives (Hessian matrix) to quickly converge to an optimal solution, particularly useful for refining high-precision operating parameters.

Jerk Control: A method that controls the rate of change of acceleration to ensure smooth motion. In high-precision alignment, minimizing jerk reduces vibrations and overshoot, ensuring smooth transitions during substrate movement.

Alignment Performance Estimator: A system that evaluates the accuracy of alignment during or after bonding, providing feedback to adjust operating parameters. It may work with the digital twin for continuous refinement.

Cross-Sectional Metrology: Measurement techniques such as TEM, STEM, or SEM, used to examine the cross-section of bonded substrates to verify alignment precision, typically after bonding. Non-destructive techniques like x-ray metrology may also be used.

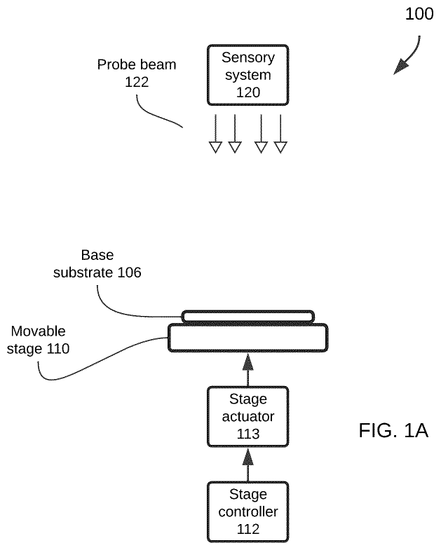

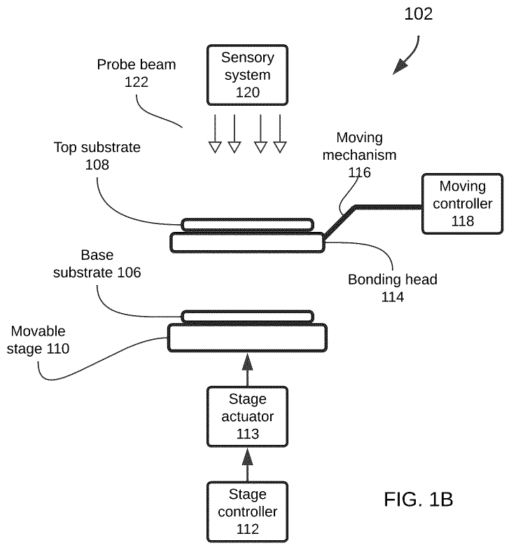

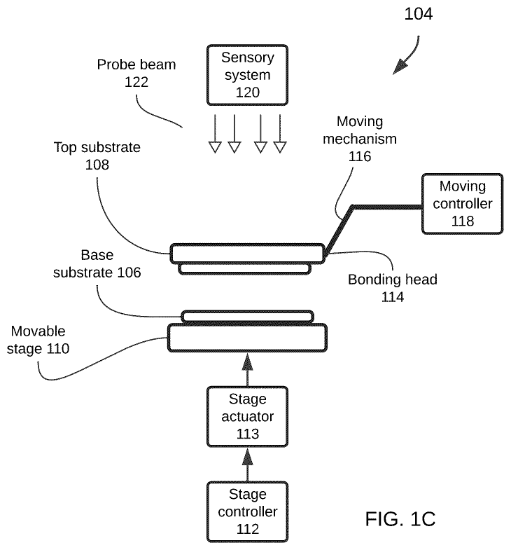

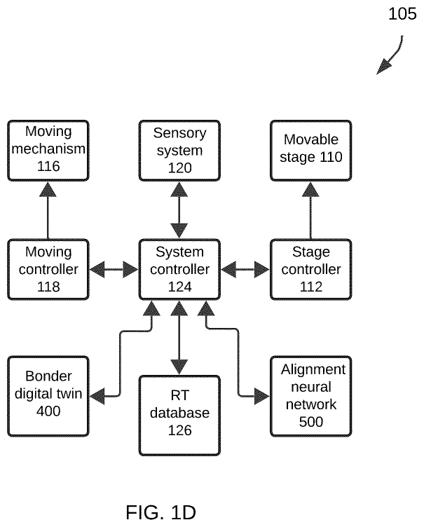

FIG. 1A depicts a schematic representation of a scenario 100 for an exemplary bonder, showing the base substrate 106 loaded onto a movable stage 110. The bonder 100 further includes a stage controller 112, which controls the movement of the stage 110 via a stage actuator 113. The stage 110 is capable of high-precision movement, with accuracy down to nanometers. The stage 110 may be an XY-stage or an XYZ-stage.

High precision moving mechanisms, such as air bearings, are critical in systems requiring ultra-smooth, frictionless motion. Air bearings use a thin film of compressed air to support the moving stage, eliminating mechanical contact and thereby reducing friction and wear found in traditional bearings. This results in stable, repeatable, and precise movements, potentially achieving nanometer accuracy. The absence of mechanical wear enhances system longevity and allows for smooth operation at high speeds. Other high-precision mechanisms, such as magnetic or flexure bearings, are also used to prioritize frictionless or low-friction movement to achieve high repeatability and stability, making them ideal for high-precision bonders. These mechanisms are particularly effective in environments where maintaining positional accuracy over extended periods and varying loads is critical.

The stage actuator 113 controls multiple operating parameters. For a high-precision stage 110, critical parameters focus on ultra-precise position control along the X and Y axes, with movements measured in nanometers. Velocity and acceleration are optimized to ensure smooth, stable positioning, minimizing overshoot and vibration. Step size or resolution is fine-tuned to allow the stage to make the smallest possible adjustments.

Accurate feedback from high-resolution encoders is essential for maintaining precise control, enabling real-time adjustments during movement. The force or torque applied by the actuator is precisely regulated to handle delicate loads with stability. Travel limits are strictly enforced to prevent the stage from exceeding its operational range, and load compensation is optimized to ensure consistent performance regardless of the load on the stage. Smooth transitions are achieved through advanced jerk control, while homing procedures ensure nanometer accuracy when returning to reference positions. In some implementations, the stage may also move vertically, functioning as an XYZ-stage.

The bonder 100 also includes a sensory system 120 positioned above the base substrate 106. The gap between the sensory system 120 and the base substrate 106 is configured to allow sufficient space for the top substrate to be placed and flipped for bonding.

The invention applies to a wide range of substrate bonding, including but not limited to W2W and D2W bonding. In W2W applications, the alignment marks on both wafers are detected, and their positions are computed in 3D space. In D2W applications, the alignment marks on the top die and the predetermined die on the base wafer are measured, and their positions are computed in 3D space.

The sensory system 120 emits a probe beam 122 toward an alignment mark on the surface of the base substrate 106, and the reflected beam is captured by the sensory system 120. The alignment mark is a 2D image that is designed so that a captured spot reveals its positional coordinates in the XY plane. The coordinates of the sensory system 120 and its probe beam 122 are calibrated relative to an origin in a 3D space.

The alignment mark is further designed so that each captured spot image, defined by the probe beam, is unique, enabling the determination of the XY coordinates of the alignment mark in the 3D space. By comparing the captured image to a set of pre-stored images, the position of the align mark in the 3D space can be determined.

The sensory system 120 may also include a sensor for measuring the distance between the sensory system 120 and the surface of the base substrate 106. Consequently, the position of the alignment mark in Z direction can also be determined. The position of the alignment mark relative to the bonding pads may vary based on lithography and related processes. This relationship, often called a registered offset, is established before the base substrate is loaded onto the stage 110. Thus, the position of the bonding pads can be determined based on the coordinates of the alignment mark and the registered offsets. All such positions can be represented by a digital twin in 3D space.

FIG. 1B shows a scenario 102 where a top substrate 108 is positioned above the base substrate 106 using a moving mechanism 116. In one implementation, a 6-axis robotic arm is used. The 6axis robotic arm is capable of movement in six degrees of freedom, allowing precise control in 3D space. It moves along three linear axes (X, Y, and Z) and rotates around the same axes (roll, pitch, and yaw). This flexibility allows the arm to perform complex tasks requiring precision.

The moving mechanism 116 is controlled by a moving controller 118, which executes multiple operating parameters. The bonding head 114 attached to the moving mechanism 116 holds the top substrate 108. The bonding head 114 may include an actuator to initiate pre-bonding of dielectric layers from the center positions of the substrates during a hybrid bonding process after the base and top substrates are in close proximity with aligned positions.

Once the top substrate 108 reaches a position parallel to the base substrate 106, the sensory system 120 is used again to determine the position of the alignment mark on the top substrate 108, employing the same method used for the base substrate 106. In some implementations, the alignment marks for the base and top substrates may be identical.

The position of the top substrate 108 is then captured by the digital twin in 3D space. FIG. 1C shows a scenario 104 where the top substrate 108 is flipped to face downward toward the base substrate 106. In some embodiments, the sensory system 120 includes distance sensors that measure positions at various locations on the substrate, enabling the system controller to determine the orientation of the top substrate 108 relative to the XY plane in 3D space.

Once the top substrate 108 is flipped, the top and base substrates are moved toward each other for bonding. The movements of the stage 110 and the moving mechanism 116 are computed based on the substrate positions in 3D space, represented by the same coordinate system. In some implementations, the base substrate 106 remains fixed while the moving mechanism 116 moves the flipped top substrate 108 toward the base substrate 106 for bonding. In other implementations, the stage 110 is an XYZ-stage, with the flipped top substrate 108 fixed while the XYZ-stage moves the base substrate 106 toward the top substrate 108. In further implementations, an XY-stage moves the base substrate 106 in the XY plane, and the moving mechanism 116 moves the top substrate 108 toward the repositioned base substrate 106 to initiate the bonding process.

Since the movable stage 110 typically moves with higher precision, the preferred embodiment is to move the base substrate 106 toward the top substrate 108 after it is flipped.

FIG. 1D depicts a schematic diagram of functional blocks of the bonder, denoted as 105. The bonder's operations are coordinated by a system controller 124, whose key function is to determine the operating parameters for the movable stage 110 and the moving mechanism 116. The bonder's digital twin 400 includes digital twins for its subsystems, such as the stage 110 and the moving mechanism 116. It also incorporates a 3D space with a coordinate system representing the positions of the base and top substrates (106 and 108) during various stages of operation. The system controller 124 relies on real-time (RT) data from the substrates, the moving mechanism, and the movable stage. The data, stored in a database 126, may include registered offsets, substrate thickness, thickness variations, and substrate warpage parameters. In one implementation, the system controller 124 utilizes an alignment neural network 400 to determine the operating parameters for the stage 110 and the moving mechanism 116, using data from the database 126 and the positions captured by the digital twin 400.

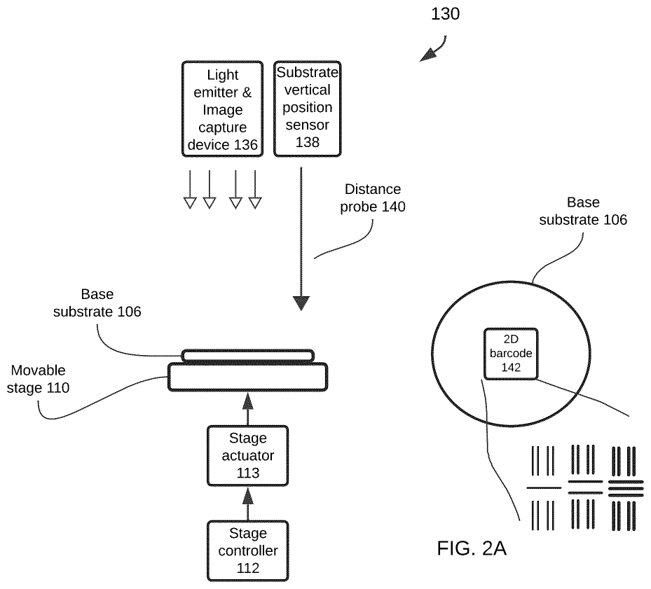

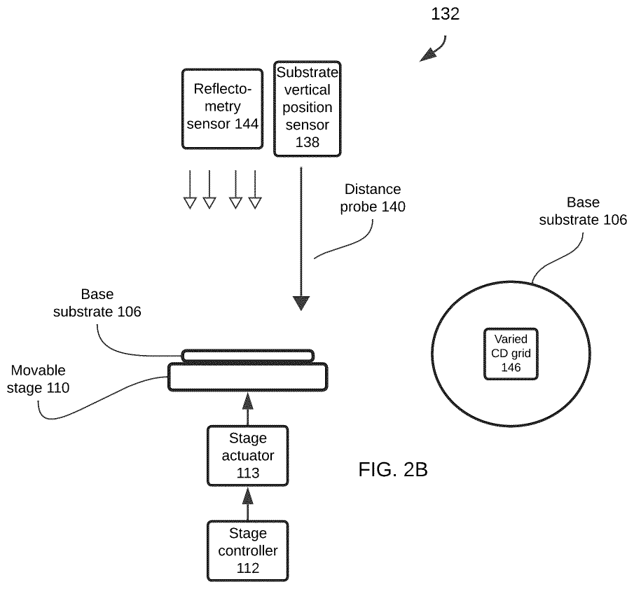

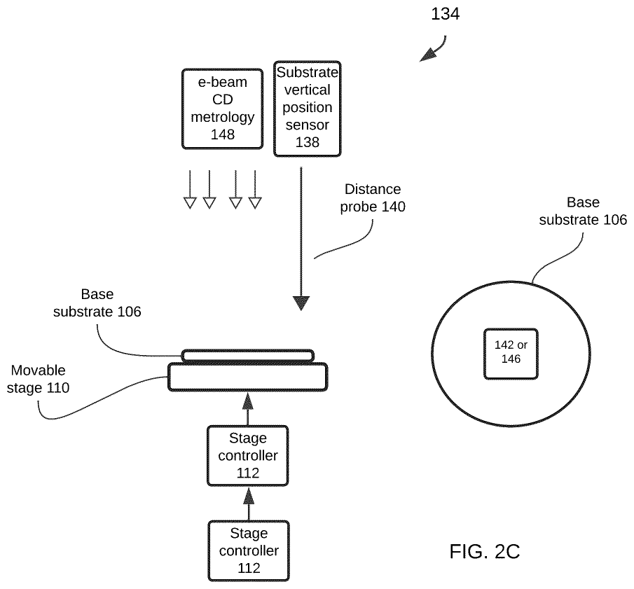

FIG. 2A illustrates a first embodiment 130 of the sensory system 120, comprising an image capture device 136 and a vertical position sensor 138. In some implementations, the image capture device 136 is a high-resolution digital camera. The camera, employing image-enhancing techniques like phase shifting, captures detailed images by manipulating the phase of light waves, enabling the accurate reproduction of fine details and textures. This method enhances clarity and sharpness. The camera includes a built-in light emitter, such as an LED or laser, to provide controlled illumination, ensuring consistent lighting for optimal image capture. The emitter reduces shadows, improves contrast, and enables more precise measurements and image analysis, especially in high-precision applications. The sensory system 120 may also include a focusing mechanism, as commonly known in the art.

The sensory system 120 also includes the vertical position sensor 138, which emits a distance probe 140 to determine the vertical position of the top substrate 108 in 3D space. The position sensor 138 can be implemented using various technologies. Laser-based sensors, such as time-of-flight (ToF) sensors, and ultrasonic sensors are commonly used for precision distance measurement. Laser-based sensors calculate the distance by measuring the time it takes for a laser beam to travel to an object and reflect back, providing high accuracy. Ultrasonic sensors, on the other hand, use high-frequency sound waves to measure distance. By calculating the time required for the sound waves to bounce back from an object, ultrasonic sensors offer another method to measure distance with precision.

The inventive concept disclosed here includes determining the position of the alignment mark in the XY plane using a 2D barcode 142 placed on the substrate, as depicted in FIG. 2A. The 2D barcode 142 is a matrix-style code that stores data in both X and Y directions, typically comprising small squares, lines, or dots. An example is showcased in FIG. 2A. It is important that for a specific position of the alignment mark, the captured image by the probe beam is unique which can be compared to a set of the pre-stored images in the system controller 124. For substrate alignment, a spot on the 2D barcode provides 2D positional information to guide the movement of the substrates during alignment. By comparing the detected spot with the known patterns, the system controller 124 calculates the exact position of the barcode in 3D space. This unique detection point acts as a digital fingerprint for the barcode's location, enabling precise determination of the substrate's position in 3D space, considering registered offsets.

This system and method offer a novel approach to substrate alignment, enabling the measurement of the substrate's position in 3D space using a common coordinate system, and calculating the required movements for accurate alignment.

FIG. 2B illustrates a second embodiment 132 of the sensory system 120, using a reflectometry sensor 144 and the vertical position sensor 138, where a varied critical dimension (CD) grid 146 is employed to determine the substrate's position in 3D space. The varied CD grid 146 includes a 2D pattern where each spot on the grid has a unique collection of lines and spaces. When measured by the reflectometry sensor, the spot's unique optical signature provides 2D positional information for guiding substrate movement during the alignment process. The grid is patterned using lithography techniques, and the variation in CD across the grid is controlled to provide distinct optical signatures at various spots. The reflectometry spectrum for each spot may be pre-established and stored in the system controller's 124 storage unit. Each spot's unique spectrum allows for precise determination of the substrate's position in 3D space, accounting for registered offsets.

This method enhances positioning precision in semiconductor processes, facilitating accurate alignment. By interpreting the varied CD grid with reflectometry, the system provides real-time positional determination, improving process control and accuracy in bonding operations.

FIG. 2C presents a third embodiment 134 of the sensory system 120, utilizing an e-beam CD metrology sensor 148 and the vertical position sensor 138, with the 2D barcode or the varied CD grid employed to determine the substrate's position in 3D space. The e-beam sensor scans a spot on the 2D barcode or the varied CD grid and interacts with the distinct electron scattering properties of the 2D patterns or the grid's lines and spaces. Each spot in the alignment mark has a uniquely defined pattern or a collection of lines and spaces, and the resulting electron beam interaction produces a specific signal corresponding to the local pattern.

The e-beam metrology system operates in a high-vacuum environment, which is necessary for the electron beam to travel uninterrupted and interact accurately with the substrate's surface. In this vacuum chamber, the substrate is positioned on a stage capable of fine movement along the X, Y, and Z axes to enable accurate scanning by the e-beam sensor. The vacuum environment prevents electron beam scattering by air molecules, ensuring high measurement precision.

As the e-beam scans the 2D barcode or the varied CD grid, it captures electron scattering signals from the localized pattern or the grid spot, which are processed to map the substrate's exact position. The localized nature of the e-beam measurement allows for nanometer-level accuracy in determining the substrate's position. This level of precision is particularly valuable for high-precision alignment and calibration during substrate bonding.

The apparatus includes an e-beam column, a high-precision substrate stage, and a vacuum chamber to maintain the high-vacuum environment. High-speed data processing capabilities are required to interpret the electron interaction data rapidly and determine the substrate's position based on the 2d barcode or the varied CD grid.

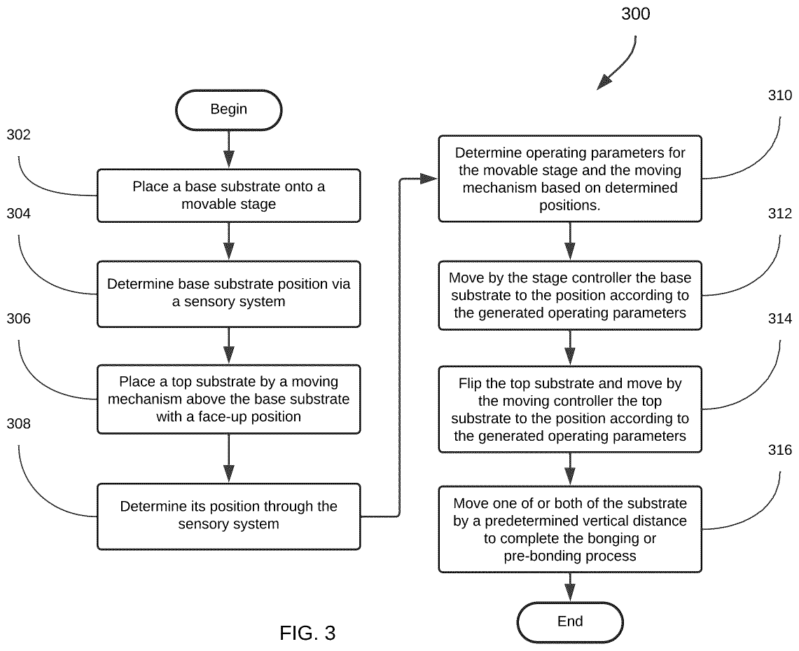

FIG. 3 illustrates a flowchart of process 300 for accurate alignment between the base substrate and the top substrate. Process 300 begins with step 302, where the base substrate 106 is placed onto the stage 110. In step 304, the position of the alignment mark, and thus the base substrate 106, is measured by the sensory system 120, considering registered offsets. In step 306, the top substrate 108 is positioned above the base substrate 106 by the moving mechanism 116, with the top substrate 108 facing upward toward the sensory system 120. In step 308, the sensory system 120 measures the position of the alignment mark on the top substrate 108, and the position of the top substrate 108 is determined, accounting for registered offsets.

The measured positions of the base substrate 106 and the top substrate 108 are captured by the system's digital twin 400, which represents the positioning system in a common 3D space with a shared coordinate system for both substrates. The sensory system 120 and its probe beam 122 are calibrated to the origin of this 3D space. In step 310, the operating parameters for the movable stage 110 and the moving mechanism 116 are determined based on the measured positions, including positions required for bonding or pre-bonding. In step 312, the system controller 124 moves the stage 110 to the position according to the determined operating parameters. In step 314, the top substrate 108 is flipped, and the moving mechanism 116 moves the top substrate 108 downward according to the system controller 124's instructions. At this stage, the base and top substrates should be aligned.

There are various ways to move the substrates into bonding or pre-bonding positions. The movable stage 110, with its higher precision, is preferably used to move the base substrate 106 toward the top substrate 108. In one implementation, the top substrate 108 is flipped, and the XYZ-stage is used to bring the base substrate 106 to the bonding or pre-bonding position.

In step 316, one or both substrates are moved by a predetermined distance to initiate bonding or pre-bonding, as used in hybrid bonding processes. An actuator in the bonding head 114 may initiate bonding or pre-bonding, starting from the centers of the substrates. During the pre-bonding step of a hybrid bonding process, the dielectric surfaces of the substrates are bonded first, with the copper bonding pads bonded later through an annealing process.

The operating parameters may be determined by leveraging the digital twin (DT) 400. In the context of the present invention, the DT 400 can model the substrate, the stage, or the moving mechanism, providing real-time feedback and optimization during the alignment process. The DT 400 may be regularly calibrated based on real-time (RT) data, such as calibration data for the stage 110 and the moving mechanism 116.

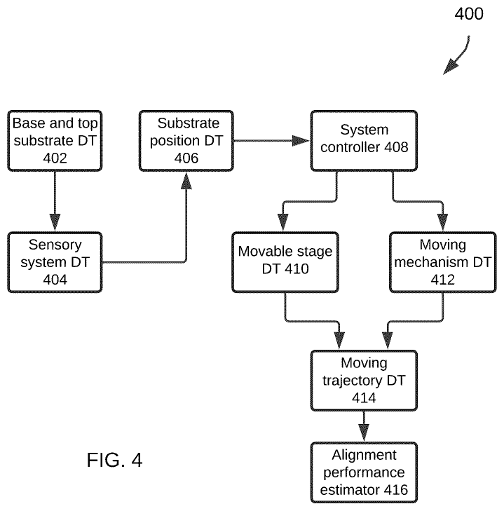

A functional diagram of the DT 400 is depicted in FIG. 4. The digital twins for the base substrate 106 and the top substrate 108, represented as 402, describe properties such as materials, thicknesses, and warpages. The positions of the substrates in 3D space are represented by the digital twin 406, while the sensory system is virtually modeled by the sensory system digital twin 404.

Outputs from these digital twins are fed into a system controller digital twin 408, which generates the operating parameters for the movable stage digital twin 410 and the moving mechanism digital twin 412. A moving trajectory digital twin 414 simulates the movement of the substrates. The alignment of the substrates at the bonding or pre-bonding positions is evaluated by an alignment performance estimator 416. One advantage of utilizing the DT 400 is its ability to capture statistical variations, such as variations in the mechanism movements, which can affect the positions of the substrates for bonding or pre-bonding.

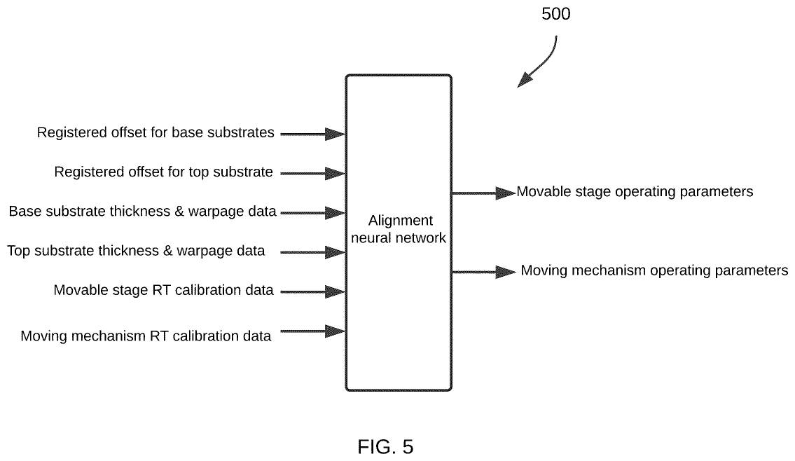

In one embodiment, the operating parameters may be determined by an alignment neural network 500, as shown in FIG. 5. The network 500 accepts various inputs, including but not limited to, the registered offsets for the alignment marks of the base substrate 106 and the top substrate 108. Other inputs may include substrate characteristics, such as materials, average thicknesses, thickness variations, and substrate warpages. The inputs may also include calibration data for the stage 110 and the moving mechanism 116, with RT calibration data being particularly useful.

It should be noted that the inputs depicted in FIG. 5 are for illustration purposes only. The actual inputs may vary depending on the specific application. The outputs from the network 500 may include trajectories for substrate movement, final positions of the substrates, and the speed of movement for both the stage 110 and the moving mechanism 116.

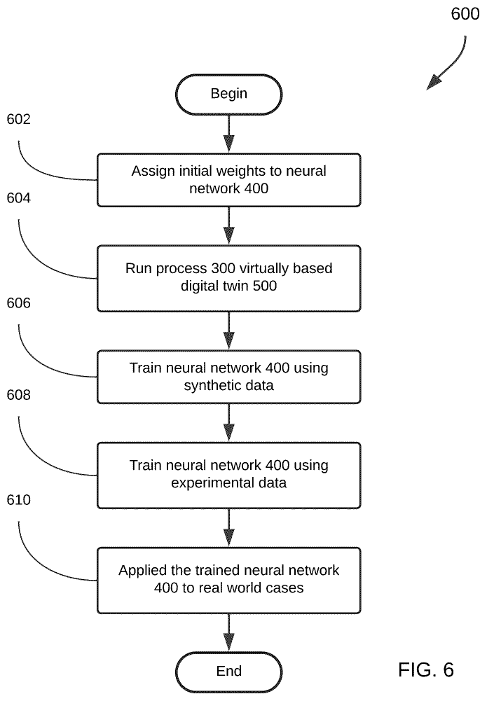

The network 500 can be trained using process 600, as outlined in the flowchart in FIG. 6. Process 600 begins with step 602, where initial weights are assigned to the network 500. In step 604, process 300 is simulated using the DT 400. In step 606, the network 500 is trained using synthetic data generated by the DT 400. In step 608, the network 500 is further trained using experimental data, which may be collected by measuring the alignment after the bonding process. In one implementation, the alignment is measured using cross-sectional techniques such as TEM, STEM, or SEM. Alternatively, non-destructive methods like x-ray metrology can be used. In step 610, the trained network 500 is deployed for real-world applications as part of the system controller 124. Once trained, the network 500 can be integrated into the DT 400 to determine operating parameters.

It should be understood that the neural network is only one approach for determining operating parameters. In another embodiment, the operating parameters may be determined using the DT 400 through an optimization procedure. To be effective, the DT 400 needs to be calibrated using RT data, especially for the stage 110 and the moving mechanism 116. The alignment error at the bonding or pre-bonding position is minimized by optimizing the operating parameters. To account for statistical variations in certain components, Monte Carlo methods can be employed to achieve statistically meaningful results.

Several well-established algorithms are commonly used for multi-parameter optimization. One such approach is stochastic gradient descent (SGD), which updates parameters iteratively using random subsets of data to compute approximate gradients. This method is computationally efficient and suitable for large-scale optimization problems. Another common method is the Newton-Raphson algorithm, which uses second-order derivatives (the Hessian matrix) to achieve faster convergence to an optimal solution, especially when high precision is required.

Additionally, genetic algorithms (GA) provide a robust optimization technique inspired by natural selection. This method is well-suited for non-differentiable or complex objective functions, as it explores a broad solution space by combining and mutating candidate solutions. Simulated Annealing (SA) is another powerful optimization method, which uses a probabilistic approach that mimics the annealing process in materials. It is particularly effective for optimizing multiple parameters in complex, non-convex landscapes.

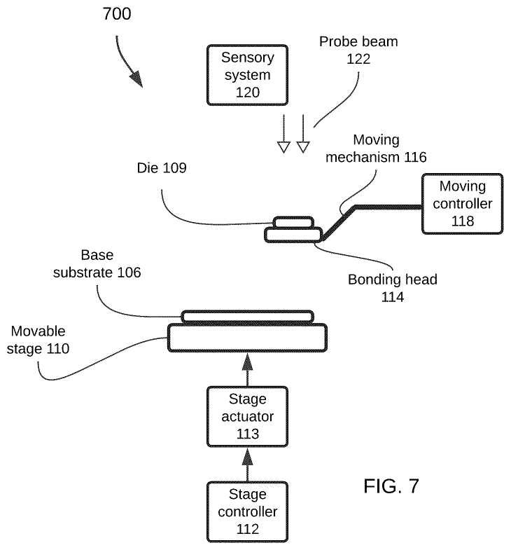

The system and methods described are generic to any substrate. For example, they can be applied to die-to-substrate bonding, as shown in FIG. 7. The substrate may be a wafer or an interposer of any shape. In this case, the moving mechanism 116 would pick up a die 109 and align it to a predetermined die with an alignment mark on the base substrate 106. In some implementations, multiple robotic arms may be used to place several dies simultaneously. Each die includes an alignment mark, which may take the form of a 2D barcode or a varied CD grid. The sensory system 120 can be applied to one or multiple dies simultaneously. In such cases, the digital twin must be adapted to account for multiple dies, rather than a single top substrate.

1. An alignment system for a bonder, comprising:
a sensory system configured to detect alignment marks on a base substrate and a top substrate, wherein said alignment marks are implemented as a 2D barcode or a varied critical dimension (CD) grid, wherein the alignment marks provide 2D positional information to guide the movement of substrates during an alignment process;
a movable stage operably supported the base substrate, wherein said stage is configured to move the base substrate in at least two directions in a plane;
a moving mechanism operably connected to a bonding head holding the top substrate, wherein said moving mechanism is configured to position the top substrate relative to the base substrate with movement in multiple degrees of freedom; and
a system controller configured to determine, in a 3D space with the same coordinate system, the positions of the base substrate, and the top substrate based on data captured by the sensory system and to generate operating parameters for bringing the base substrate and the top substrate to aligned positions for bonding or pre-bonding.

2. The alignment system of claim 1, wherein the system further includes a digital twin comprising virtual representations of the substrates, the movable stage, the moving mechanism, and the sensory system.

3. The alignment system of claim 2, wherein the digital twin is calibrated according to a predetermined frequency based on real-time data including calibration data for the movable stage and the moving mechanism.

4. The alignment system of claim 3, wherein the system controller is further configured to utilize a neural network to determine the operating parameters.

5. The alignment system of claim 1, wherein the sensory system includes an optical image capture device for detecting the 2D barcode.

6. The alignment system of claim 1, wherein the sensory system includes a reflectometry sensor to detect the varied CD grid.

7. The alignment system of claim 1, wherein the sensory system includes an e-beam metrology sensor to detect the 2D barcode or the varied CD grid.

8. The alignment system of claim 1, wherein the sensory system further comprises a substrate vertical position sensor, selected from a laser-based time-of-flight (ToF) sensor or an ultrasonic sensor, to determine the vertical position of the top and base substrates.

9. The alignment system of claim 4, wherein the neural network is initially trained using synthetic data generated by the digital twin, and subsequently refined using experimental data obtained from post-bonding measurements.

10. The alignment system of claim 4, wherein the inputs to the neural network include registered offsets for the alignment marks, substrate materials, substrate thickness variations, substrate warpage, and calibration data from the movable stage and the moving mechanism, and the outputs of the neural network include the operating parameters.

11. A method for aligning substrates by a system controller, comprising:
detecting alignment marks on a base substrate and a top substrate using a sensory system, wherein said alignment marks provide 2D positional information to guide movement of the substrates during an alignment process;
determining the positions of the base substrate and the top substrate in a 3D space using a digital twin that captures the positions of the substrates with the same coordinate system;
generating operating parameters based on the determined positions, wherein said operating parameters are used to move a movable stage holding the base substrate and a moving mechanism for a bonding head holding the top substrate; and
moving the base substrate using the stage and the top substrate using the moving mechanism in response to the generated operating parameters to bring the substrate into aligned positions for bonding or pre-bonding.

12. The method of claim 11, wherein the moving mechanism flips the top substrate, and the stage moves the base substrate to the aligned position for bonding or pre-bonding.

13. The method of claim 11, wherein the digital twin further comprising virtual representations of the substrates, the movable stage, and the moving mechanism, and the sensory system.

14. The method of claim 13, wherein the digital twin is calibrated using real-time data including real-time calibration data for the movable stage and the moving mechanism.

15. The method of claim 14, wherein the digital twin is used to determine the operating parameters via an optimization procedure to minimize the misalignment of the substrates.

16. The method of claim 15, wherein the optimization procedure further includes generating statistical data of the alignment.

17. The method of claim 14, wherein the operating parameters are generated by a neural network trained using synthetic data generated by the digital twin and further refined by experimental data obtained from post-bonding measurements.

18. A bonder for bonding a base substrate and a top substrate, comprising:
a. an alignment system, including:
a sensory system configured to detect alignment marks on a base substrate and a top substrate, wherein said alignment marks are implemented as a 2D barcode or a varied critical dimension (CD) grid, wherein the alignment marks provide 2D positional information to guide the movement of substrates during an alignment process;
a movable stage operably supported the base substrate, wherein said stage is configured to move the base substrate in at least two directions in a plane;
a moving mechanism operably connected to a bonding head holding the top substrate, wherein said moving mechanism is configured to position the top substrate relative to the base substrate with movement in multiple degrees of freedom;
a system controller configured to determine, in a 3D space with the same coordinate system, the positions of the base substrate and the top substrate based on data captured by the sensory system and to generate operating parameters for bringing the base substrate and the top substrate to aligned positions for pre-bonding step of a hybrid bonding process; and
b. a bonding head holding the top substrate for initiating the pre-bonding step.

19. The bonder of claim 18, wherein the system controller utilizes a neural network, trained initially by synthetic data generated by the digital twin and further refined using experimental data from post-bonding processes, to optimize the operating parameters for the movable stage and the moving mechanism.

20. The bonder of claim 18, wherein the base substrate further consists of a selection from a wafer, a silicon interposer, an organic interposer, a glass substrate, and an organic substrate.
